(19) United States
(12) Patent Application Publication
(10) Pub. No.: US 2011/0100681 A1
(43) Pub. Date: May 5, 2011

(54) SUBSTRATE-MOUNTED CIRCUIT MODULE HAVING COMPONENTS IN A PLURALITY OF CONTACTING PLANES

(76) Inventors: Peter Kimmich, Schoenaich (DE); Quoc-Dat Nguyen, Reutlingen (DE)

(21) Appl. No.: 12/736,611

(22) PCT Filed: Apr. 2, 2009
(86) PCT No.: PCT/EP2009/053914

§ 371 Date: Jan. 1, 2011

(30) Foreign Application Priority Data
Apr. 28, 2008 (DE) 10 2008 001 414.1

(51) Int. Cl. H05K 1/18; H05K 1/05; H01K 3/10

(52) U.S. Cl. 174/252; 174/255; 29/850

(57) ABSTRACT

In a circuit module having components that are fastened to a substrate, the substrate includes a carrier layer made of metal and having a first surface, a first insulating layer bordering directly on the carrier layer being situated on the first surface. The substrate also includes a first wiring layer bordering directly on the first insulating layer, which conducts electrically and is situated on the first insulating layer. The substrate includes a first contact plane, which runs along the first surface, at least one of the components being directly connected electrically to the carrier layer in the first contact plane.

### BACKGROUND OF THE INVENTION

1. FIELD OF THE INVENTION

The present invention relates to a circuit module in which electronic components fastened on the surface are fastened on a substrate.

2. DESCRIPTION OF RELATED ART

Such a fastening structure is known from the field of surface-mounted components (surface-mounted technology SMT).

Published German patent application document DE 100 38 092 A1 describes an electrical module in which a chip is connected to a cooling body, an IMS substrate providing printed circuit traces to which the chip is connected. A metallic base plate, which forms the carrier of the substrate, it is true, is used for thermal connection as well as for mechanical stabilization, but is separated from the chip via an insulating layer. Consequently, this document shows a connecting structure based exclusively on printed circuit traces, which is separated from the metallic carrier plate of the substrate by an insulating layer. In the same way, U.S. Pat. No. 6,441,520 B1 shows a power circuit in which an IMS substrate (insulated metal substrate) is also used. This fastening unit provided on the IMS substrate includes components that are connected to an upper metal layer of the substrate. However, the metal layer, which forms printed circuit traces, is separated from the carrier layer by a continuous insulating layer; the metallic carrier layer of the IMS substrate is thus continuously covered by an insulating layer. In this document too, the metallic carrier plate of the IMS-substrate is used only for mechanical stability and for heat dissipation. Both documents show a substrate having a metal layer which, on the contact side of the substrate, continuously and completely carries an insulating layer.

The IMS substrates (IMS—insulated metal substrate) are used as printed circuit boards for power components, a metallic carrier layer being provided for both heat dissipation and increasing the mechanical stability. However, in more complex circuits, for instance, in three-phase rectifier bridges, long printed circuit traces come about, since only the uppermost layer, that is, the wiring layer provided on the insulating layer, which provides printed circuit traces, is used for connecting the components. Since, based on the flowing currents, the printed circuit traces provided in the connecting layer have to have a minimum width, a large surface requirement comes about, and at the same time long wiring paths.

It is therefore an object of the present invention to provide a connecting technology that minimizes the abovementioned disadvantages.

### BRIEF SUMMARY OF THE INVENTION

The circuit module according to the present invention, as well as the production method according to the present invention, enable the positioning of components having improved electromagnetic compatibility, reduced reactive power and reduced space requirement. The present invention enables a compact construction while employing usual cost-effective substrates, which are able to be processed using extensively known processing technologies. When using the present invention, while employing usual substrates, one is able to provide an additional contact plane which clearly simplifies the wiring by printed circuit traces. The reduced complexity leads to a reduced reactive power and to a saving in wiring surface. In addition, the present invention leads to improved heat dissipation of power components that are connected according to the present invention. The carrier layer is used as a mechanical/electrical contacting plane as well as a heat sink/heat dissipation. In addition, bonds and other connections are saved which are provided in addition to the printed circuit traces. The components, as well as the associated terminals of the circuit module, according to the present invention, are able to be positioned at greater degrees of freedom and higher flexibility compared to the related art. In addition, the present invention makes possible a combination of power current applications and control applications on the same substrate. In other words, power components are able to be positioned together with control components or logic components on the same substrate. This additionally increases the integration density. Furthermore, the present invention enables the production of contacts between components and the substrate via a low-temperature sintering connection, such a connection leading to an increased resistance to temperature changes.

By contrast to substrate-based connections according to the related art, when the present invention is used, the carrier layer of a power substrate, which is made of metal for heat dissipation and to increase the mechanical stability, is used for the electrical connection of components. Up to now, electrical components were completely separated from the carrier layer via a continuous insulating layer, but, according to the present invention, a recess is provided in the insulating layer which directly covers the carrier layer. Because of this recess, a first surface of the carrier layer is exposed, and space is provided for accommodating a component and/or a contact element for connection to the carrier layer. In order to accommodate the component, preferably, at the recess in the insulating layer, there is also provide a recess in the wiring layer that lies above it, usually a copper foil. The recess in the wiring layer is preferably aligned with the recess in the insulating layer, or is at least provided to be flush with it on one side, whereupon according to one preferred embodiment of the present invention, the recess in the wiring layer providing a surface into which the recess in the insulating layer fits in, a frame forming between the larger recess in the wiring layer and the recess in the insulating layer. Moreover, the recesses may be equivalent, have the same measurements and be positioned aligned one over the other.

As the recess, one should understand, in this connection, a complete opening in the insulating layer and the wiring layer for the entire thickness of the insulating layer and the wiring layer. The surface of the carrier layer, i.e. the first surface bordering on the insulating layer, thus forms a first contact plane which connects all the components connected to it electrically to one another. For each component that is connected to the carrier layer in the first contact plane, an appertaining opening is preferably provided. In a known manner, a second contact plane forms the wiring layer that is provided on the insulating layer, the wiring layer being preferably a metal layer, which is able to be patterned by etching, for example, so as to develop printed circuit traces. The circuit module according to the present invention may include further contact planes, formed by additional wiring layers, which are respectively mounted on insulating layers. A stacked arrangement of insulating layers and wiring layers is achieved thereby, which alternate along a direction perpendicular to the carrier layer plane. By contrast to the related art, in which the number of wiring layers corresponds to the number of contact planes, the use of the carrier layer of the substrate as an electrical conductor provides an additional contact plane. The electrical insulation of this additional contact plane is able to be achieved using known insulation elements (mica insulators or insulation foils, insulating socket, etc.).

According to one first example embodiment, a three-layered IMS substrate is used having a metallic carrier layer, an insulating layer and a wiring layer. According to a second example embodiment, a substrate is used having a metallic carrier layer and respectively two alternating insulating layers and wiring layers, one of the insulating layers separating one of the wiring layers from the carrier layer. Both of the example embodiments may further include solder resist, that has been applied as a layer onto the wiring layer, or rather, the uppermost wiring layer. Moreover, the solder resist may also be applied to other surfaces, for instance, onto an insulating layer over which an opening in the wiring layer is provided, or onto the carrier layer which is exposed by recesses.

Depending on the depth of the recess in the wiring layer and in the insulating layer, and as a function of the height of the component located there, the recess may also provide lateral protection for the components that are mounted directly on the carrier layer. According to the present invention, a direct contact between component and carrier layer or wiring layer is designated as a direct electrical connection, the direct contact preferably including a soldering connection (for instance, using soldering paste) or a low-temperature sintering connection. For this purpose, the respective components preferably include contact surfaces that extend in one plane, the respective contact surface of the carrier layer and the respective contact surface of the wiring layer preferably extending essentially in the same plane. The components, preferably electrical and electronic SMD components, thus preferably include contact surfaces that permit a direct contact to a layer lying below it, that is, a carrier layer or a wiring layer. Basically, in connecting a component in the first contact plane, i.e. to the carrier layer, the same connecting technique may be used as for the connection in a second or further contact plane, that is, between the component and the wiring layer or one of the wiring layers.

The carrier layer is preferably a coated or uncoated piece of sheet metal, made of copper, aluminum, brass, steel or a combination of these, for example. Generally, the carrier layer forms a metallic base which, according to the present invention, besides for heat dissipation and for mechanical stability, is used for the electrical contacting of components.

The insulating layer is preferably a dielectric, for example, a dielectric plastic or a dielectric polymer, an epoxy resin, a fiber-reinforced polymer, a hard paper material, a ceramic material or a combination of these, for instance, a multilayer layer. In spite of its electrically insulating properties, the material is preferably a heat conductor, in order to be able to transfer the heat to the carrier layer, according to the heat generation of the power application. The carrier layer itself is preferably connected to a heat sink at a second surface, that is opposite to the first surface, as will be described below.

According to one example embodiment, the wiring layer includes a coated or an uncoated metal layer, a copper layer, a copper layer tinned on one side, a piece of sheet metal or a combination of these. As noted before, the wiring layer is preferably patterned to provide for printed circuit traces. The wiring layer is applied directly onto an insulating layer below it, preferably by adhesion, the insulating layer too being preferably adhered to the layer below, i.e. a wiring layer or the carrier layer. Because of the adhesion connection, two layers adhered to each other border directly on each other.

A circuit module according to the present invention also preferably includes bonding connections or solder bridges between surfaces of components facing away from the carrier layer, having one of the wiring layers or for the electrical connection between various printed circuit traces, contact surfaces or pads that are developed by the wiring layer or wiring layers.

A lower side of the carrier layer, that is, the second surface facing away from the insulating layer, preferably has a heat sink or a connection (i.e. contact surface) for a heat sink. For this, the second surface is preferably provided with a heat-conducting surface contact, or a heat sink in the form of a cooling body is used which provides a flat connecting surface, and this is brought into contact with the second surface in a heat-conducting manner, and which also provides cooling fingers at an angle for this. Between the second surface and the heat sink, a layer is preferably provided which acts in a heat-transferring manner, for instance, a layer of mica, heat-conducting paste or the like. This layer is preferably electrically insulating. The heat sink may further be connected via (electrically insulating) connecting elements to the substrate, for instance, to the carrier layer.

In order to apply cooling bodies onto the second surface of the carrier layer, an electrically insulating heat-conducting paste is used, with or without electrically insulating beads as spacers. Alternatively, one may use a heat-conducting, electrically insulating foil. The thickness of the foil or the thickness of the layer of the heat-conducting paste and the beads is preferably adapted to the voltage that is present at the carrier layer. In this instance, breakdown effects must be taken into consideration.

Besides the connecting possibilities on the electrical contacting that were mentioned above, a punch grid may be used in addition, which provides at least one sheet metal section, and which is able to be connected to the carrier layer of the substrate or to a wiring layer. The punch grid thus includes connected sheet metal sections, the sheet metal sections, before fastening, being connected to one another, for example, by an encircling frame. In order to fasten the sheet metal sections to the substrate, the former are preferably pressed onto the substrate, for instance, using a stamp or a punch, in order thus to provide electrical as well as mechanical contact. After the sheet metal sections have been connected to the substrate in this manner, all sheet metal sections are detached from the frame (dam bar) by stamping, laser cutting, shearing or by other separating working processes. The sheet metal sections do not necessarily all have to be separated from one another, but may in part remain connected to one another, by separating them from the frame in an appropriately connected way. The tools provided for pressing the sheet metal sections onto the substrate may include flat structures, since the underliner, i.e. the substrate of the sheet metal section to be fastened on it is flat. The planes of the tool are possibly arranged at different heights, for instance, when one sheet metal section is to be pressed onto a wiring layer and one sheet metal section onto the deeper-lying carrier layer. The applying of the punch grid, which includes the sheet metal sections, may be carried out within the scope of a transfer mold process, so that the substrate, that is already provided with components, obtains effective protection of the electronics because of the transfer mold process.

The punch grid may be provided made of a sheet metal, for instance a coated or uncoated sheet steel, copper sheet, brass sheet or the like.

The components provided in the circuit module preferably form a motor control or the power output stage of a motor control or a DC/DC converter or a power output stage of a DC/DC converter. The components of the circuit module preferably form a three-phase system, for instance, a full-wave rectifier for a three-phase current system or a corresponding three-phase output stage for full-wave control with three MOSFET pairs. The voltage supply potential may be provided between the carrier layer and the wiring layer, the wiring layer, the carrier layer and an insulating layer lying between them being able to form a usual three-layered substrate. A substrate may be equipped with one or a plurality of complete three-phase controls. Furthermore, components of the circuit module may be used as a bridge circuit having four MOSFET's, there being present either an output motor voltage or an input voltage between opposite connection locations of the bridge circuit. The respective connections in the bridge circuit may be provided by the carrier layer, at least one wiring layer and possibly having bonding connections.

The concept on which the present invention is based is further implemented by a method according to the present invention, in which a substrate is provided having a carrier layer, an insulating layer lying above it and a wiring layer on top of the insulating layer, and the insulating layer and the wiring layer are processed in order to remove surface sections of the wiring layer and the insulating layer to provide recesses. The recesses in layers lying above that (e.g. wiring layer(s)) preferably correspond to the surface section that is removed from the insulating layer. The step of removing the respective surface sections, so as to provide the recesses, includes lasering or milling all insulating layers and wiring layers that lie above the carrier layer. Thereupon, according to the present invention, at least one component is positioned, i.e. an electrical or an electronic component, the component being placed into the recesses and fastened there. The component is fastened on the carrier layer by producing a direct electrical connection between a surface contact of the component and a correspondingly exposed surface section of the carrier layer. At the same time, a mechanical connection and a heat-conducting connection are produced via the electrical connection. The surface section is a section of the first surface in which the first contact plane runs. The first contact plane is the contact plane which, in comparison to substrate patternings according to the related art, provides an additional electrical connecting plane.

As the components which are inserted into the recesses, according to the present invention, and are connected to the carrier layer, or which are applied onto one of the wiring layers for electrical contacting, SMD-capable types of construction are suitable of electrical components such as power output stages, power components, MOSFET's, IGBT's, diodes, shunt resistors, capacitors, especially ceramic capacitors, SMD inductances, electrical connecting elements, such as surface mounted plugs or sockets, and the like. Particularly suitable are high performance components, whose heat is dissipated (among other things) by the insulating layer via the connection with the carrier layer or directly via the carrier layer. Besides the carrier layer, additional heat sinks are also suitable, such as cooling bodies that are applied at the side, of an electrical component transferring heat, that is opposite to the side facing the carrier layer. The cooling bodies, that are situated on the component, may be the same cooling bodies that are mounted on the carrier layer, or may differ from them. As cooling bodies to be fastened on a component or on the carrier layer, cooling bodies made of metal, graphite or ceramic are suitable, for example, which have an appropriately extensive shape for giving off the heat to the surroundings. In the same manner as the cooling bodies applied on the carrier layer, cooling bodies applied to components using insulating heat-conducting paste, with or without nonconductive beads as spacers, or using an insulating, heat-conducting foil, may be fastened electrically insulated.

### BRIEF DESCRIPTION OF THE DRAWING

FIG. 1 shows a cross section through a circuit module equipped with components, according to the present invention.

### DETAILED DESCRIPTION OF THE INVENTION

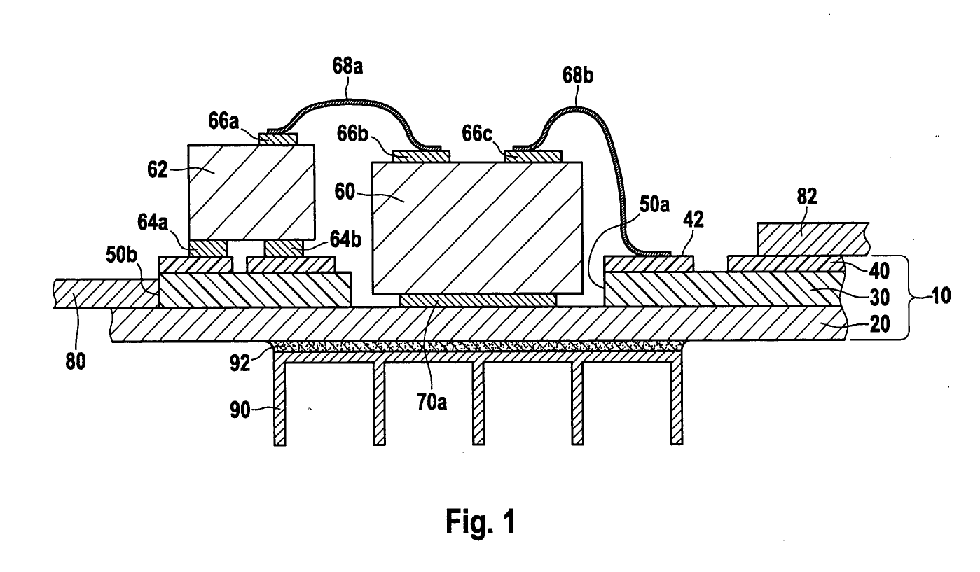

FIG. 1 shows a circuit module having a substrate 10, which provides a carrier layer 20 provided to be made of metal, an electrically insulating insulating layer 30 and an electrically conducting wiring layer 40, printed circuit traces by patterning and/or pads and electrical contact surfaces (not shown). Carrier layer 20 is continuous, whereas insulating layer 30, lying over it, has a first recess 50a according to the present invention, in which the first surface of carrier layer 20 is exposed and a component 60 is in electrical contact with carrier layer 20 via contact elements 70a. A second recess 50b also provides an exposed contact surface of the first surface of carrier layer 20, in section 50b a sheet metal section 80 having been pressed onto carrier layer 20. Sheet metal section 80 was a punch grid during the production process, and was separated from the rest of the punch grid during production, especially from a blanking frame. Wiring layer 40 also has interruptions, the latter being used for patterning, and thus for the development of printed circuit traces and contact pads in wiring layer 40.

While component 60, that is connected to carrier layer 20, is situated in the first contact plane, a second component 62 is connected to the second contact plane that is formed by wiring layer 40. For this purpose, component 62, as does component 60, has contact surfaces 64a, b, which are in contact with two different contact pads or printed circuit traces of wiring layer 40. In comparison to component 62, component 60 has a continuous contact surface 70a, so that, in contrast to component 62, only one contact transition is implemented, because of the continuous surface and the relatively large surface content, a heat transfer having low resistance being provided between component 60 and carrier layer 20, to enable good heat transportation. Contact surfaces 64a, b, 70a don't end together with the outer circumference of the respective component, whereas in an example not shown, the contact surfaces end together with the edges of the lower side of the components, that is, the component's surface directed toward the substrate. Consequently, contact surface 70a forms a first contact plane, together with carrier layer 20, contact elements 64a, b form a second contact plane with wiring layer 40, upper contact surfaces 66a, b, c, together with bonding wires 68a, b providing a third contact plane. In principle, a bonding connection may be provided between two components, as is shown in exemplary fashion using contact surfaces 66a, b and bonding wire 68a. Moreover, the bonding connection may also be provided between a contact surface of a component and the second contact plane (wiring layer 40), as is shown in exemplary fashion in FIG. 1 by contact surface 66c, bonding wire 68b and contact pad 42 of wiring layer 40. The bonding connection is produced by pressing wires made of (soft) metal onto the contact surface, that is, for example by pressing aluminum or gold wires onto the respective contact surfaces or onto the contact pad of wiring layer 40. A further possibility (not shown) of the bonding connection is the connection between an upper contact surface of a component, that is provided on the side of a component facing away from the substrate, and carrier layer 20. To do this, a recess according to the present invention is provided in insulating layer 30 as well as in wiring layer 40, in order to expose the first surface of carrier layer 20 there, and in order to provide, for instance, an electrical connection to carrier layer 20 by pressing bonding wires onto carrier layer 20. Basically, besides the abovementioned connection of components by bonding connections to contact surfaces of components, one may also provide a terminal connection to carrier layer 20 or to wiring layer 40 by a bonding connection. If, for example, a contact pad of wiring layer 40 or carrier layer 20 is to be contacted, bonding connections are used, preferably having a larger wiring diameter, and having a plurality of wires, in order to make possible a large current transition. Such a connection may be provided, for example, at the place in FIG. 1 at which sheet metal section 80 contacts carrier layer 20, or it may be provided where, in FIG. 1, a further sheet metal section 82 contacts a contact pad developed by wiring layer 40. A contact pad of wiring layer 40 (or of the wiring layers) may be connected via one or more bonding wires to an additional contact pad of a wiring layer 40 or to carrier layer 20 (at an exposed place).

Moreover, FIG. 1 shows a cooling body 90 which is connected to a second surface of carrier layer 20, that is opposite the first surface, via a heat transferring connection, such as an electrically insulating, heat transferring foil or insulating heat-conducting paste 92. The second surface of carrier layer 20 extends at the lower side of substrate 10, and thus at the lower side of carrier layer 20, while the first surface extends on the side of carrier layer 20, which faces insulating layer 30.

As a matter of principle, the dimensions shown in FIG. 1 are not true to scale, but are greatly enlarged in part, for better illustration. In particular, the thickness of carrier layer 20 is preferably greater than the thickness of insulating layer 30 and greater than the thickness of wiring layer 40. The respective layer thicknesses comply with the desired rigidity of carrier layer 20, the resistance to breakdown of insulating layer 30 and the application of current in wiring layer 40. In comparison to components 60 and 62, cooling body 90 is shown greatly diminished, and is merely supposed to show symbolically a suitable location of heat dissipation. A cooling body is preferably connected to carrier layer 20 over a major part of the second surface, especially at places which are opposite to contact surfaces of components (particularly components situated directly on carrier layer 20). The components fastened to substrate 10, shown in exemplary fashion in FIG. 1 using reference numerals 60 and 62, may be of the same size or have different sizes, may have different sizes or the same size of contact surfaces on the side facing carrier layer 20, and may particularly generate heat to different extents. Those components, which give off a large quantity of heat during operation, are preferably connected to carrier layer 20, for example, MOSFET output stage transistors or IGBT output stage transistors or power rectifiers, whereas components having slight heat emission, such as capacitors or coils are preferably fastened on one of wiring layers 40 or on wiring layer 40. To improve the heat radiation, components having a large heat emission may also have a cooling body on the side facing away from carrier layer 20, for example, in the case of component 60, at the location at which contact surfaces 66b and c are provided, a cooling body connection replacing contact surfaces 66b and c. The entire lower side of components is preferably used as contact layer, so that the contact layers are bordered by the outer edges of the lower side of the components.

When a high performance MOSFET or IGBT is used as component 60, contact surfaces 66b and c are preferably not of equal size, but rather, the contact surface which represents the anode, cathode, emitter or collector terminal is clearly larger compared to the other contact surface. In this case, the smaller contact surface corresponds to the control terminal, i.e. the base terminal or the gate terminal. Accordingly, the bonding connections between the control terminal and wiring layer 40 are carried out using comparatively thin wires and a small number of bonding wires, whereas the larger surface is preferably connected using thicker wires in a bonding connection, a larger number of wires also preferably being used. In the case of a connection of high performance terminals (such as anode, cathode, collector or emitter terminals), a larger number of wires, for instance, more than two, or four may thus be used, which have a thicker wire diameter than wires used to connect control terminals. For the connection of high performance terminals, instead of wires having a circular (or square) cross section, one may also use wires or sheet metal having an extended cross section, whose cross section corresponds to a plurality of thicker bonding wires, because of its wide shape, or is greater than the total cross section of a plurality of bonding wires.

Basically, to form a substrate 10 according to the present invention, the recess may be milled or removed in another way from the layers lying over carrier layer 20, for instance, by lasering. According to another exemplary embodiment, the layers that lie over carrier layer 20 are provided with recesses reaching through the entire layer thickness, for instance, by stamping, cutting or the like, before the connection (by adhesion/pressing) to carrier layer 20 and before the connection among one another. This example may be used for circuit modules, in which the wiring layer(s) 40 and the insulating layer(s) 30 are coherent even after the provision of all the recesses, for instance, in layouts in which the outer edging of the recess also corresponds to the area that is removed, with no material remaining within the edging of the recess. Wiring layers 40 may be patterned using photolithography and etching.

In general, according to the present invention, passive or electrical components are provided so as to be, at least in part, positioned and fastened in the recess, so as there to be directly connected to carrier layer 20 electrically, mechanically and in a heat-conducting manner. Besides the components mentioned, contact elements for electrical contacting may also be situated, at least in part, in the recess. That is why, according to the present invention, a component should be understood to be a part that has an electrical function. The electrical function may be simple, for instance, providing a plug contact or a soldering contact for carrier layer 20, or it may be complex, for instance, switching a strong current, as is provided by a MOSFET, thyristor, TRIAC or an IGBT.

1-10. (canceled)

11. A circuit module for connecting components, comprising:
a substrate including:
a carrier layer made of metal and having a first surface, wherein a first contact plane of the substrate extends along the first surface of the carrier layer;
a first insulating layer situated on the first surface of the carrier layer and bordering directly on the carrier layer; and
an electrically conducting first wiring layer situated on the first insulating layer and bordering directly on the first insulating layer;
wherein at least one recess is provided in the first insulating layer and the first wiring layer, wherein the recess is configured to accommodate at least one component, and wherein the carrier layer is configured to electrically connect the at least one component directly to the carrier layer in the first contact plane.

12. The circuit module as recited in claim 11, the substrate further comprising:
a second insulating layer and a second wiring layer, wherein the second insulating layer is situated on the first wiring layer and borders directly on the first wiring layer, and the second wiring layer is situated on the second insulating layer and borders directly on the second insulating layer.

13. The circuit module as recited in claim 11, wherein the at least one recess extends through the first insulating layer and the first wiring layer, and wherein the circuit module includes the at least one component situated in the at least one recess, and wherein the at least one component is directly and electrically connected to the carrier layer in the recess.

14. The circuit module as recited in claim 13, wherein the at least one component includes a contact surface where the at least one component is fastened to the carrier layer, and wherein the contact surface provides one of: (i) a direct electrical connection between the at least one component and the carrier layer; or (ii) a direct electrical connection between the at least one component and the first wiring layer in a second contact plane extending along the first wiring layer.

15. The circuit module as recited in claim 13, wherein:
the carrier layer includes at least one of copper, aluminum, and steel;
the insulating layer includes at least one of a dielectric, a dielectric polymer, an epoxy resin, a fiber-reinforced polymer, a hard paper material, a ceramic material, and a heat-conducting material; and
the wiring layer includes at least one of a copper layer, a copper layer tinned on one side, and a sheet metal.

16. The circuit module as recited in claim 13, wherein the at least one component is:
at least one of a MOSFET, an IGBT, a shunt, a capacitor, a ceramic capacitor, an inductor, an unpackaged electronic component, a packaged electronic component, and a cooled electronic component connected to an associated cooling body using one of a soldering connection, an adhesive connection, or a low-temperature sintering connection; and
configured as one of:
a high-performance component;
a surface-mounted component;
a component in electrical contact, by one of a soldering connection, an adhesive connection or a low-temperature sintering connection, to one of the carrier layer or the first wiring layer; or
a component electrically connected, using one of a bonding connection or a solder bridge, to one of the carrier layer or the wiring layer via a surface of the electrically connected component facing away from the substrate.

17. The circuit module as recited in claim 13, further comprising:
one of a heat sink or a heat-conducting surface contact;
wherein the carrier layer includes a second surface located opposite to the first surface, and wherein one of: (i) the heat sink is connected to the second surface in a heat-transferring manner, or (ii) the heat-conducting surface contact forms at least a part of the second surface.

18. The circuit module as recited in claim 13, further comprising:
at least one sheet metal section including one of coated steel sheet metal, uncoated steel sheet metal, copper sheet metal, or brass sheet metal, wherein the at least one sheet metal section is connected via press-on contacting to one of the carrier layer or a surface of the wiring layer facing away from the carrier layer.

19. The circuit module as recited in claim 13, wherein the circuit module includes at least two MOSFET pairs, each MOSFET pair including two performance MOSFETs connected via a serial connection, wherein the performance MOSFETs of each pair are assigned to different voltage half-waves, and wherein the serial connection includes a tapping forming one pole of a symmetrical voltage supply.

20. A method for producing a substrate-based circuit, the method comprising:
providing a substrate including:
a carrier layer made of metal;
an electrically insulating layer directly situated on the carrier layer; and
an electrically conducting wiring layer directly situated on the insulating layer;
providing a recess extending through the entire thickness of the insulating layer and the wiring layer by removing a section of the wiring layer and a section of the insulating layer;
positioning at least one electrical component in the recess; and
fastening the at least one electrical component on the carrier layer by a direct electrical connection of a surface contact of the component to a surface section of the carrier layer exposed by the removal of the sections of the wiring layer and the insulating layer.
